(19) United States
(12) Patent Application Publication
(10) Pub. No.: US 2025/0244675 A1
(43) Pub. Date: Jul. 31, 2025

(54) PATTERNING METHOD AND PATTERNING DEVICE

(71) Applicant: Tokyo Electron Limited, Minato-ku, Tokyo (JP)

(72) Inventors: Kazuki YAMADA, Nirasaki-shi, Yamanashi (JP); Reiko TSUZUKI, Nirasaki-shi, Yamanashi (JP); Tomohito YAMAJI, Nirasaki-shi, Yamanashi (JP)

(21) Appl. No.: 18/848,185

(22) PCT Filed: Mar. 13, 2023
(86) PCT No.: PCT/JP2023/009518

§ 371 Date: Sep. 18, 2024

(30) Foreign Application Priority Data
Mar. 25, 2022 (JP) 2022-049226

(51) Int. Cl. G03F 7/26; G03F 7/36; H01L 21/308

(52) U.S. Cl. CPC G03F 7/265; G03F 7/36; H01L 21/3086

(57) ABSTRACT

A patterning method includes an infiltration operation and an etching operation. The infiltration operation includes infiltrating, into a photoresist film, a material for increasing a selectivity of an exposed portion and an unexposed portion formed by exposure on the photoresist film provided on a surface of a substrate, and the etching operation includes dry-etching the photoresist film on which the infiltration operation has been performed.

### TECHNICAL FIELD

The present disclosure relates to a patterning method and a patterning device.

### BACKGROUND

Patent Document 1 discloses a technique for improving etching resistance after a resist is formed by exposing the resist after film formation to a metal-containing gas that contains a metal to infiltrate the metal into the resist.

### PRIOR ART DOCUMENT

### Patent Document

Patent Document 1: Japanese Laid-Open Patent publication No. 2020-038929

### SUMMARY

The present disclosure provides a technique which is capable of developing an exposed pattern on a photoresist film by a dry process.

According to one embodiment of the present disclosure, a patterning method includes an infiltration operation and an etching operation. The infiltration operation includes infiltrating, into a photoresist film, a material for increasing a selectivity of an exposed portion and an unexposed portion formed by exposure on the photoresist film provided on a surface of a substrate. The etching operation includes dry-etching the photoresist film on which the infiltration operation has been performed.

According to the present disclosure, it is possible to develop an exposed pattern on a photoresist film by a dry process.

### BRIEF DESCRIPTION OF DRAWINGS

FIG. 1 is a diagram schematically illustrating an example of an overall flow of a substrate processing according to an embodiment.

FIG. 2 is a block diagram illustrating an example of a configuration of a patterning device according to an embodiment.

FIG. 3 is a diagram illustrating an example of a processing flow of a patterning method according to an embodiment.

FIG. 4 is a diagram conceptually illustrating an example of a substrate according to an embodiment.

FIG. 5 is a diagram illustrating an example of a profile of silicon contained in a photoresist film according to an embodiment.

FIG. 6 is a diagram illustrating an example of a profile of a dry etching on the photoresist film according to an embodiment.

FIGS. 7A to 7C are diagrams conceptually illustrating an example of results obtained by etching a substrate according to an embodiment.

FIGS. 8A to 8C are diagrams conceptually illustrating another example of results obtained by etching the substrate according to an embodiment.

FIG. 9 is a diagram illustrating an example of an overall flow of a substrate processing including a lithography process in the related art.

### DETAILED DESCRIPTION

Hereinafter, an embodiment of a patterning method and a patterning device disclosed herein will be described in detail with reference to the drawings. Further, the patterning method and patterning device disclosed herein are not limited to this embodiment.

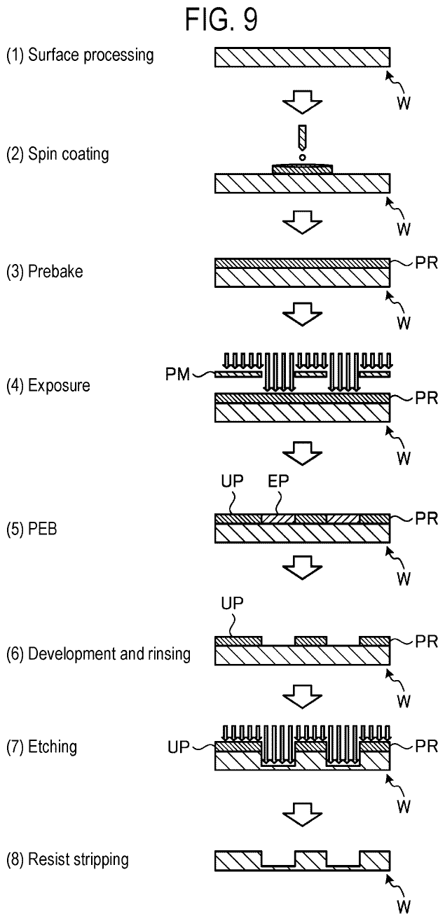

In recent years, with large-scale integration (LSI) and high performance of a semiconductor integrated circuit, a pattern formed on a surface of a substrate is becoming finer. The pattern is formed on the substrate by a lithography process. FIG. 9 is a diagram illustrating an example of an overall flow of a substrate processing including a lithography process in the related art. In the substrate processing illustrated in FIG. 9, processes (1) to (8) are performed on a substrate W. The substrate W is, for example, a silicon substrate such as a silicon wafer. A target film on which a pattern is to be formed is formed on the substrate W. In surface processing (1), a predetermined pre-processing such as cleaning the substrate W is performed. In a spin coating (2), the substrate W is rotated while being coated with a photoresist liquid so that a photoresist film PR is formed on the substrate W. In a prebake (3), the substrate W is heated to evaporate a solvent contained in the photoresist film PR. In an exposure (4), light such as ultraviolet light is irradiated via a photomask PM on which a pattern is formed to form a latent image of a pattern having an exposed portion EP and an unexposed portion UP on the photoresist film PR. Here, the photoresist film PR is of a negative type, in which the exposed portion EP remains due to development, and a positive type, in which the unexposed portion UP remains due to the development. In the case of the negative type, the exposure is performed using the photomask PM that transmits a portion to be left on the photoresist film PR. In the case of the positive type, the exposure is performed using the photomask PM that does not transmit the portion to be left on the photoresist film PR. In a post exposure bake (PEB) (5), a reaction is promoted by heating. In a development and rinsing (6), a latent image of the photoresist film PR is developed with a solvent such as a developer, and the solvent used in the development is rinsed away. FIG. 9 illustrates the case in which a positive type of development is performed, and the unexposed portion UP has remained and the exposed portion EP has dissolved and disappeared. The processes (1) to (6) correspond to the lithography process. The pattern on the photoresist film PR is developed by the lithography process. In an etching (7), etching is performed using the photoresist film PR as a mask to process the substrate W. In a resist stripping (8), the photoresist film PR is stripped and removed. Thus, the pattern is formed on the substrate W.

However, if the pattern becomes finer, development of the exposed pattern on the photoresist film PR by a wet process such as the development and rinsing (6) may result in pattern defects such as roughness deterioration due to expansion of the photoresist film PR or pattern collapse due to surface tension. On the other hand, development by a dry process does not cause the above matters. However, in the development by the dry process, it is difficult to develop the exposed pattern on the photoresist film PR because a difference in etching rate between the exposed portion EP and the unexposed portion UP is small. Therefore, a technique capable of developing the exposed pattern on the photoresist film PR by the dry process is needed.

### Embodiment

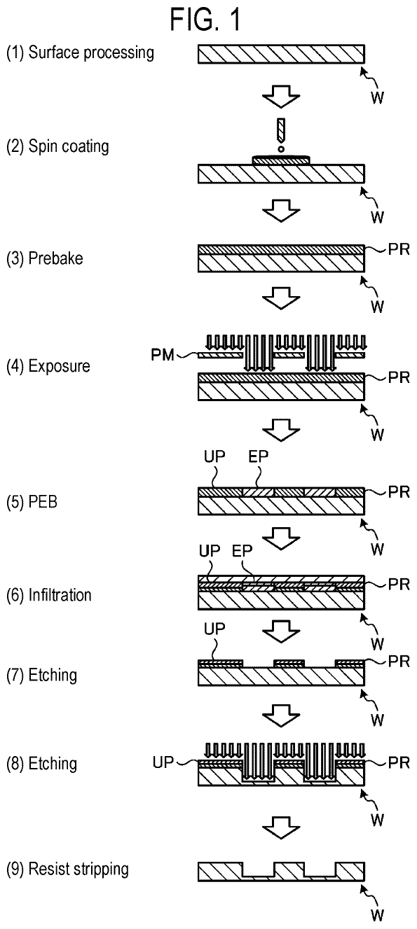

A patterning method according to an embodiment will now be described. First, an example of an overall flow of a substrate processing including a lithography process according to an embodiment will now be described. FIG. 1 is a diagram schematically illustrating the example of the overall flow of the substrate processing according to an embodiment. In FIG. 1, the substrate processing including processing of a patterning method according to the embodiment is illustrated. In the substrate processing according to the embodiment, the development and rinsing (6) in the substrate processing in the related art illustrated in FIG. 9 is changed to the infiltration (6) and the etching (7). In the substrate processing illustrated in FIG. 1, processes (1) to (9) are performed. The processes (1) to (5), (8), and (9) in FIG. 1 are the same as the processes (1) to (5), (7), and (8) in FIG. 9, and therefore descriptions thereof will be omitted.

A latent image of a pattern having an exposed portion EP and an unexposed portion UP is formed on a photoresist film PR of a substrate W by the exposure (4). The photoresist film PR is, for example, an organic film containing a photosensitive resin as a main component. Examples of the photoresist film PR may include a KrF photoresist or an extreme ultraviolet (EUV) photoresist.

In the infiltration (6), a material for increasing a selectivity of the exposed portion EP and the unexposed portion UP is infiltrated into the photoresist film PR of the substrate W. A difference in etching rate occurs according to a difference in infiltration depth, i.e., a difference in degree of denaturation of the photoresist film PR. For example, in the infiltration (6), the substrate W is exposed to gas containing the material for increasing the selectivity of the exposed portion EP and the unexposed portion UP, and the material is infiltrated into the photoresist film PR. Since infiltration depths differ in the exposed portion EP and the unexposed portion UP, a difference in the etching rate occurs from a point at which the difference in infiltration depth occurs, and thus the pattern may be developed. In addition, the pattern may be developed even when the amount of infiltration differs in the exposed portion EP and the unexposed portion UP. This includes a case in which the material reacts only at any portion. When the amount of infiltration differs, the difference in the etching rate occurs from a starting time point of etching to form the pattern.

Thus, examples of the material for increasing the selectivity of the exposed portion EP and the unexposed portion UP of the photoresist film PR may include a metallic element and a metalloid element. Examples of the metal element may include aluminum (Al), titanium (Ti), and germanium (Ge). An example of the metalloid element may include silicon (Si). For example, when the silicon is infiltrated into the photoresist, examples of the material used for infiltration may include, as promising candidates, N-(trimethylsilyl) dimethylamine (TMSDMA), bis (trimethylsilyl) amine (HMDS), and hexachlorodisilane (HCD). When the aluminum is infiltrated into the photoresist, trimethylaluminum (TMA), triethylaluminum (TEA), and the like are used as examples of the material for infiltration. When the titanium is infiltrated into the photoresist, TDMAT, TiCl₄, and the like are used as examples of the material for infiltration. The materials for infiltration are infiltrated into the photoresist film PR by exposing the photoresist film PR to vapor by vaporization, bubbling, or skimming.

In the etching (7), the photoresist film PR into which the material is infiltrated is dry-etched. In the photoresist film PR, since the selectivity of the exposed portion EP and the unexposed portion UP increases by performing the infiltration (6), and the exposed portion EP is etched deeper than the unexposed portion UP during the etching. In the etching (7), the exposed portion EP of the photoresist film PR may be etched away and the unexposed portion UP may remain, by appropriately controlling an etching time. However, depending on a combination of the photoresist film PR and the material used for infiltration, a portion to be removed and a portion to be left among the exposed portion EP and the unexposed portion UP may be reversed.

In the substrate processing illustrated in FIG. 1, the photoresist film PR is patterned by the infiltration (6) and the etching (7). The infiltration (6) and the etching (7) correspond to processing of a patterning method of the present disclosure.

### Configuration of Patterning Apparatus

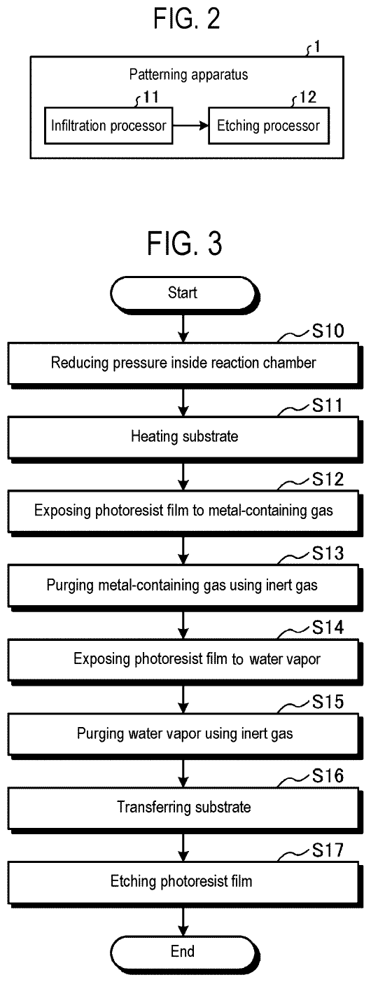

Next, an example of a patterning device which performs the infiltration (6) and the etching (7) will now be described. FIG. 2 is a block diagram illustrating an example of a configuration of a patterning device 1 according to an embodiment. The patterning device 1 according to the embodiment includes an infiltration processor 11 and an etching processor 12.

The infiltration processor 11 is a unit which implements the infiltration (6). The infiltration processor 11 may be configured to use a reaction chamber in which the substrate W on which the exposed portion EP and the unexposed portion UP are formed on the photoresist film PR is placed, a heater configured to heat the substrate W, a supplier configured to supply gas such as a metal-containing gas into the reaction chamber, and an exhauster configured to exhaust an interior of the reaction chamber.

The etching processor 12 is a unit which implements the etching (7). The etching processor 12 may be configured to use, for example, a dry etching device. For example, the etching processor 12 performs reactive ion etching with an etching gas. An example of the etching gas may include a hydrogen-containing gas such as a hydrogen (H₂) gas.

In addition, in the patterning device 1, each of the infiltration processor 11 and the etching processor 12 do not need to be configured as one unit.

### Patterning Method

Next, a processing flow of a patterning method according to an embodiment will be described. Hereinbelow, an example will be described in which a metallic element, such as aluminum, titanium, or germanium, or a metalloid element, such as silicon, is infiltrated as a material for increasing the selectivity of the exposed portion EP and the unexposed portion UP of the photoresist film PR. FIG. 3 is a diagram illustrating an example of the processing flow of the patterning method according to an embodiment. In FIG. 3, details of the infiltration (6) and the etching (7) are illustrated. Before processing of the patterning method is performed, the substrate W on which, for example, the processes (1) to (5) in FIG. 1 are performed, is transferred to the infiltration processor 11 and placed inside the reaction chamber. The patterning device 1 according to the embodiment executes processing illustrated in FIG. 3.

The infiltration processor 11 reduces an internal pressure of the reaction chamber so that the interior of the reaction chamber is kept in a depressurized state (step S10). The infiltration processor 11 heats the substrate W placed inside the reaction chamber to raise a temperature of the substrate W to a predetermined temperature suitable for the infiltration (step S11).

The infiltration processor 11 exposes the photoresist film PR to gas containing the material that increases the selectivity of the exposed portion EP and the unexposed portion UP under predetermined conditions. For example, the infiltration processor 11 exposes the photoresist film PR to gas containing the metallic element or the metalloid element under the predetermined conditions (step S12). Hereinafter, the gas containing the metallic element or the metalloid element is referred to as a “metal-containing gas.”

Then, the infiltration processor 11 purges the metal-containing gas from the reaction chamber using an inert gas such as N₂ (step S13). Subsequently, the infiltration processor 11 exposes the photoresist film PR to water vapor under the predetermined conditions (S14). Then, the infiltration processor 11 purges the water vapor from the reaction chamber using the inert gas such as N₂ (step S15). Processing of steps S12 to S15 described above may be repeated multiple times.

The patterning device 1 takes out the substrate W from the infiltration processor 11 and transfers the same to the etching processor 12 (step S16). In the case in which the infiltration processor 11 and the etching processor 12 are configured as one unit, step S16 may be omitted.

The etching processor 12 etches the photoresist film PR of the substrate W (step S17). For example, the etching processor 12 dry-etches the photoresist film PR by reactive ion etching based on a H₂ gas. By appropriately controlling an etching time, the exposed portion EP of the photoresist film PR may be removed and the unexposed portion UP may remain.

The “temperature of the substrate W” used herein refers to a temperature of at least a part of the substrate W including the photoresist film PR and may be a surface temperature of the photoresist film PR. The “predetermined temperature” used herein may be within a range of room temperature to 200 degrees C. The “room temperature” refers to a temperature in a natural state without external heating or cooling, and is, for example, a temperature (e.g., 25 degrees C.) selected in a range of 1 degree C. to 40 degrees C. When the temperature of the substrate W is lower than the room temperature, it is often impossible to obtain sufficient energy to exceed an activation barrier for infiltrating the metallic element into the photoresist film PR (e.g., for causing a nucleophilic substitution reaction). The temperature of 200 degrees C. exemplified as an upper limit of the temperature of the substrate W is a temperature sufficiently higher than a transition temperature of the photoresist film PR.

The “predetermined conditions” used when exposing the photoresist PR to the metal-containing gas include the temperature of the substrate W, a gas flow rate, an exposure time, and pressure. The amount of infiltration of the metal element and the metalloid element into the photoresist film PR increases as the temperature of the substrate W increases, and decreases as the temperature of the substrate W decreases. The amount of infiltration increases as the gas flow rate of the metal-containing gas increases, and decreases as the gas flow rate decreases. The amount of infiltration increases as the exposure time of the photoresist film PR to the metal-containing gas increases, and decreases as the exposure time decreases. The amount of infiltration increases as the internal pressure of the reaction chamber increases, and decreases as the internal pressure decreases.

Processing of steps S14 and S15 is not necessarily essential. However, the infiltration may be promoted by exposing the photoresist film PR to water vapor after exposure to the metal-containing gas. The “predetermined conditions” used when exposing the photoresist film PR to the water vapor include the temperature of the substrate W, the gas flow rate, the exposure time, and the internal pressure. An effect of infiltration promotion due to the water vapor increases as the temperature of the substrate W increases, and decreases as the temperature of the substrate W decreases. The effect of infiltration promotion also increases as the gas flow rate of the water vapor increases, and decreases as the gas flow rate decreases. The effect of infiltration promotion increases as the exposure time of the photoresist film PR to the water vapor increases, and decreases as the exposure time decreases. The effect of infiltration promotion increases as the internal pressure of the reaction chamber increases, and decreases as the internal pressure decreases.

The conditions used when exposing the photoresist film PR to the water vapor (the temperature of the substrate W, the gas flow rate, the exposure time, the internal pressure, and the like) may be the same as conditions used when exposing the photoresist film PR to the metal-containing gas or may be set to be different from the conditions used when exposing the photoresist film PR to the metal-containing gas.

The amount of infiltration of the metallic element or the metalloid element into the photoresist film PR may be in a range of 4 atomic % to 20 atomic %. When the amount of infiltration is lower than 4 atomic %, an effect of increasing etching resistance of the photoresist film PR is often not substantially recognized. When the amount of infiltration is higher than 20 atomic %, organic properties inherent to the photoresist film PR (e.g., solubility in an alkaline solution, and the like) are impaired, and the strippability of the photoresist film PR is deteriorated, thereby making it difficult to strip the photoresist film PR from a film to be etched in the resist stripping (9).

Control of the amount of infiltration may be implemented by adjusting the conditions during exposure to the metal-containing gas, the conditions during exposure to the water vapor, and the number of repetitions of the operations of S12 to S15. For example, the internal pressure during exposure to the metal-containing gas may be in a range of 0.05 Torr to 760 Torr. When the internal pressure is lower than 0.05 Torr, the amount of infiltration may not reach 4 atomic %, and when the internal pressure is higher than 760 Torr, the amount of infiltration may exceed 20 atomic %.

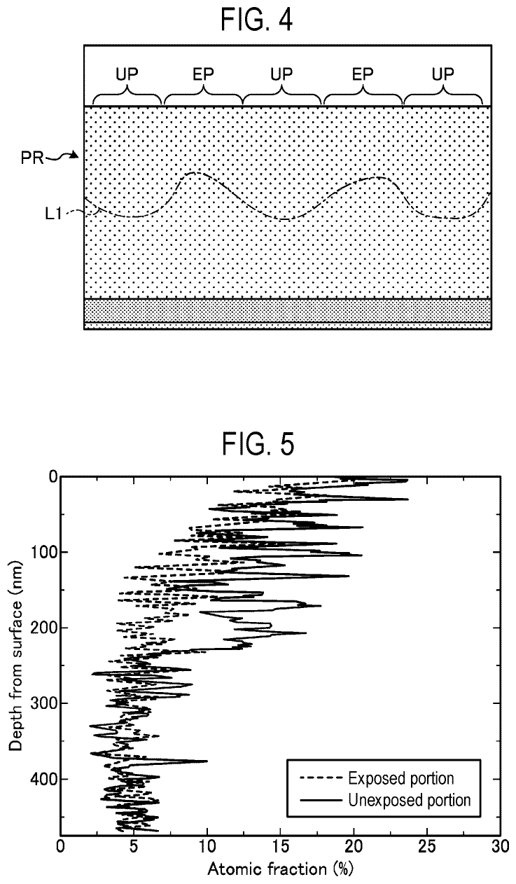

FIG. 4 is a diagram conceptually illustrating an example of the substrate W according to an embodiment. In FIG. 4, the substrate W on which silicon is infiltrated into the photoresist film PR by exposure to TMSDMA is illustrated. The substrate W includes the photoresist film PR formed thereon. The photoresist film PR is alternately provided with the exposed portion EP and the unexposed portion UP. In FIG. 4, a depth to which silicon is infiltrated into the photoresist film PR is denoted by a line L1. As denoted by the line L1, the silicon is infiltrated deeper into the unexposed portion UP than into the exposed portion EP.

FIG. 5 is a diagram illustrating an example of a profile of silicon contained in the photoresist film PR according to an embodiment. In FIG. 5, a silicon content ratio is illustrated with respect to a depth from the surface of the photoresist film PR for the exposed portion EP and the unexposed portion UP. For example, around a depth of 0 to 150 nm, the silicon content ratio is slightly higher in the unexposed portion UP than in the exposed portion EP. Around a depth of 150 to 250 nm, the silicon content ratio is clearly higher in the unexposed portion UP than in the exposed portion EP. This shows that silicon is infiltrated more deeply into the unexposed portion UP than into the exposed portion EP. In this way, the infiltration depth of silicon differs in the unexposed portion UP and the exposed portion EP.

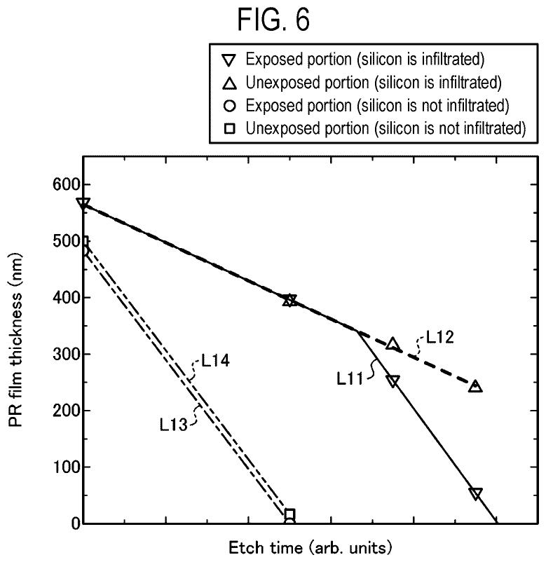

FIG. 6 is a diagram illustrating an example of a profile of a dry etching on the photoresist film PR according to an embodiment. In FIG. 6, when the photoresist film PR is dry-etched, the remaining film thickness of the photoresist film PR with respect to an etching time is illustrated as a profile. In FIG. 6, the profile of the exposed portion EP of the photoresist film PR into which silicon is infiltrated is denoted by a line L11, and the profile of the unexposed portion UP of the photoresist film PR into which silicon is infiltrated is denoted by a line L12. Further, in FIG. 6, as Comparative Example, the profile of the exposed portion EP of the photoresist film PR into which silicon is not infiltrated is denoted by a line L13, and the profile of the unexposed portion UP of the photoresist film PR into which silicon is not infiltrated is denoted by a line L14.

As denoted by the lines L13 and L14, the photoresist film PR into which silicon is not infiltrated is etched deeply in a short etching time and thus has a high etching rate as compared to the photoresist film PR into which silicon is infiltrated, denoted by the lines L11 and L12.

The etching resistance of the photoresist film PR increases due to infiltration of silicon. Therefore, as denoted by the lines L11 and L12, the exposed portion EP and the unexposed portion UP of the photoresist film PR into which silicon is infiltrated have a low etching rate as compared to those denoted by the lines L13 and L14. In addition, as denoted by the line L11, the etching rate of the exposed portion EP increases midway. This is because, as denoted by the line L1 in FIG. 4 and as illustrated in FIG. 5, an infiltration range of the exposed portion EP in which silicon is infiltrated is shallower than an infiltration range of the unexposed portion UP and thus the etching rate of the exposed portion EP is low in the infiltration range, but when the depth is deeper than the infiltration range, the etching rate of the exposed portion EP changes to about the same level as the lines L13 and L14. On the other hand, in the unexposed portion UP, as denoted by the line L12, the etching rate remains low because the infiltration range of silicon is deep.

As a result, in the photoresist film PR into which silicon is infiltrated, the exposed portion EP is etched deeper than the unexposed portion UP due to a difference in the infiltration range between the exposed portion EP and the unexposed portion UP.

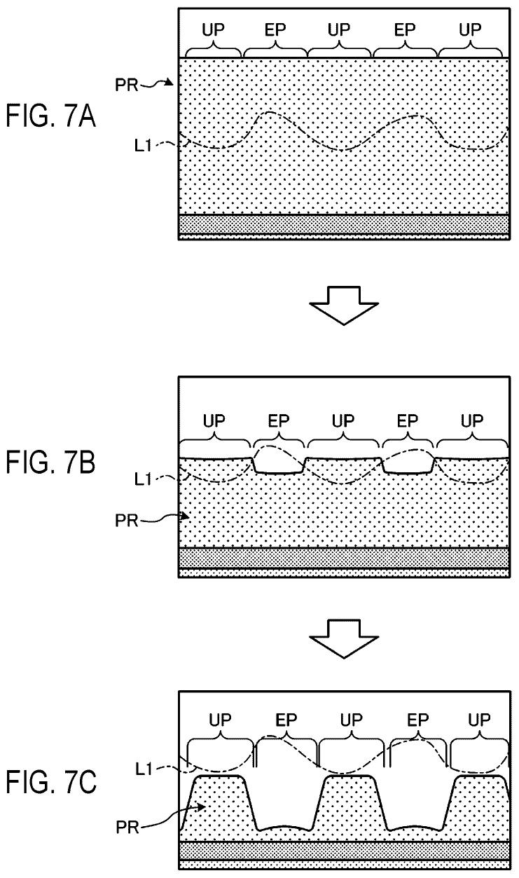

FIGS. 7A to 7C are diagrams conceptually illustrating an example of results obtained by etching the substrate W according to an embodiment. In FIGS. 7A to 7C, changes in the photoresist film PR are illustrated when etching the substrate W on which silicon is infiltrated into the photoresist film PR by exposing the photoresist film PR to TMSDMA. FIG. 7A illustrates the photoresist film PR before etching. The photoresist film PR is alternately provided with the exposed portion EP and the unexposed portion UP. In FIGS. 7A to 7C, the depth of infiltration of silicon into the photoresist film PR is approximately denoted by a line L1. FIG. 7B illustrates a state in which the photoresist film PR has been etched for 7.5 minutes using an etching gas containing a H₂ gas. The unexposed portion UP is etched in an infiltration range in which silicon is infiltrated. On the other hand, the exposed portion EP is etched deeper than the unexposed portion UP because the etching rate becomes faster when the depth exceeds the infiltration range. FIG. 7C illustrates a state in which the photoresist film PR has been etched for 9.5 minutes using the etching gas containing the H₂ gas. The unexposed portion UP has been etched up to about the infiltration range. On the other hand, the exposed portion EP has been etched sufficiently deeper than the unexposed portion UP. By appropriately controlling the etching time, the exposed portion EP of the photoresist film PR may be removed and the unexposed portion UP may remain. This makes it possible to develop a pattern of a latent image having the exposed portion EP and the unexposed portion UP by the dry process. The photoresist film PR may have scum, which is a residue of the photoresist, at an interface with a lower layer. The scum may be removed by reactive ion etching based on an O₂ gas.

In the above embodiment, the case in which the substrate W on which silicon has been infiltrated into the photoresist film PR is developed by one round of etching using the H₂ gas has been described by way of example. However, the present disclosure is not limited to this embodiment. For example, the substrate W may be developed by two rounds of etching. As an example, a first etching and a second etching may be performed on the substrate W. In the first etching, a first gas capable of etching the photoresist film PR into which a material is infiltrated is used to perform the etching up to a depth, which is deeper than a depth to which the material is infiltrated into the exposed portion EP and shallower than a depth to which the material is infiltrated into the unexposed portion UP. For example, in the case of the photoresist film PR into which silicon is infiltrated, an etching gas containing a hydrogen-containing gas (e.g., a H₂ gas) is used to perform the etching up to a depth, which is deeper than a depth to which the material is infiltrated into the exposed portion EP and shallower than a depth to which the material is infiltrated into the unexposed portion UP. In the second etching, after the first etching, the etching is performed using a second gas capable of etching the photoresist film PR into which the material is not infiltrated more than the photoresist film PR into which the material is infiltrated. For example, in the case of the photoresist film PR into which silicon is infiltrated, the etching is performed using an etching gas containing an oxygen-containing gas (e.g., an O₂ gas).

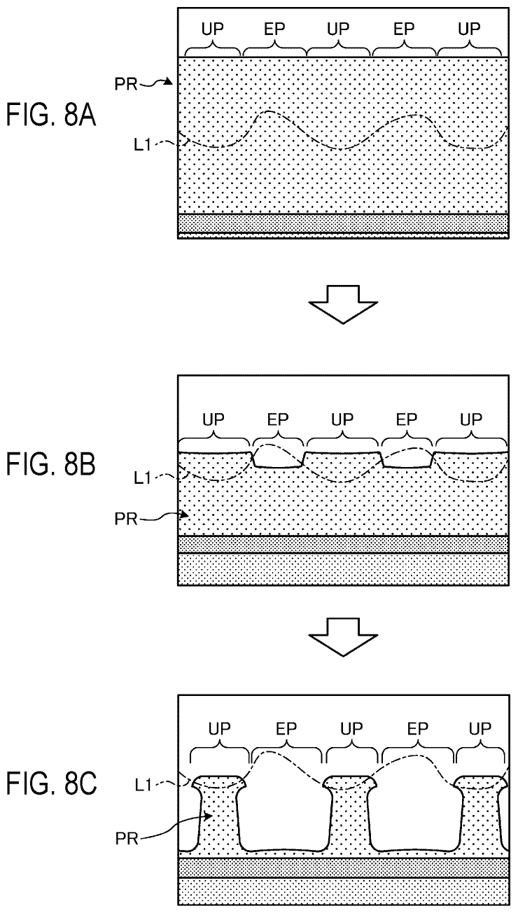

FIGS. 8A to 8C are diagrams conceptually illustrating another example of results obtained by etching the substrate W according to an embodiment. In FIGS. 8A to 8C, changes in the photoresist film PR when the substrate W on which silicon is infiltrated into the photoresist film PR by exposure of the photoresist film PR to TMSDMA is subjected to two rounds of etching are illustrated. FIG. 8A illustrates the photoresist film PR before etching. The photoresist film PR is alternately provided with the exposed portion EP and the unexposed portion UP. In FIGS. 8A to 8C, the depth of infiltration of silicon into the photoresist film PR is approximately denoted by a line L1. FIG. 8B illustrates a state in which the photoresist film PR has been etched for 7.5 minutes using an etching gas containing a H₂ gas. Both the exposed portion EP and the unexposed portion UP are etched. The unexposed portion UP is etched in an infiltration range in which silicon is infiltrated. On the other hand, the exposed portion EP is etched deeper than the unexposed portion UP because the etching rate becomes faster when the depth exceeds the infiltration range. Subsequently, as illustrated in FIG. 8B, the photoresist film PR is etched using an etching gas containing an O₂ gas. FIG. 8C illustrates a state in which the photoresist film PR has been etched for 50 seconds using the etching gas containing an O₂ gas. In the unexposed portion UP in which the amount of infiltration of silicon is large, a silicon oxide film is formed on a surface layer to function as an etching stop layer. The exposed portion EP is etched because the amount of infiltration of silicon is small (or silicon is not infiltrated) and thus the silicon oxide film may not be formed. As a result, high selectivity is generated in the exposed portion EP and the unexposed portion UP. By appropriately controlling the etching time, the exposed portion EP of the photoresist film PR may be removed and the unexposed portion UP may remain. This makes it possible to develop a pattern of a latent image having the exposed portion EP and the unexposed portion UP by the dry process.

As described above, the patterning method according to the embodiment may increase etching selectivity of the exposed portion EP and the unexposed portion UP, and therefore the exposed pattern on the photoresist film PR may be developed by the dry process. Thus, the patterning method according to the embodiment may suppress the occurrence of pattern defects such as roughness deterioration or pattern collapse in the pattern of the developed photoresist film PR even when the pattern is finer.

### Effects

As described above, the patterning method according to the embodiment includes the infiltration operation (steps S12 to S15) and the etching operation (step S17). The infiltration operation includes infiltrating, into a photoresist pattern PR, a material for increasing selectivity of an exposed portion EP and an unexposed portion UP formed by exposure on the photoresist film PR provided on a surface of a substrate W. The etching operation includes dry-etching the photoresist film PR on which the infiltration operation has been performed. Thus, the patterning method may develop then exposed pattern on the photoresist film PR by the dry process.

The infiltration operation includes exposing the substrate W to gas containing the material. Thus, the patterning method may infiltrate the material into the photoresist film PR.

The material is the metallic element or the metalloid element. The metal is any one of aluminum, titanium, and germanium. The metalloid is silicon. The infiltration operation includes infiltrating the material deeper into the unexposed portion UP than into the exposed portion EP. Thus, the patterning method may increase the selectivity of the exposed portion EP and the unexposed portion UP.

The amount of infiltration of the metallic element or the metalloid element into the photoresist film PR is in a range of 4 atomic % to 20 atomic %. Thus, the patterning method may suppress a decrease in strippability of the photoresist film PR while increasing etching resistance of the photoresist film PR.

The etching operation includes etching the exposed portion EP deeper than the unexposed portion UP. Thus, the patterning method may develop the exposed pattern on the photoresist film PR by the dry process.

The etching operation includes performing a first etching with a first gas capable of etching the photoresist film PR into which the material is infiltrated, up to a depth, which is deeper than a depth to which the material is infiltrated into the exposed portion and shallower than a depth to which the material is infiltrated into the unexposed portion, and performing a second etching with a second gas capable of etching the photoresist film PR into which the material is not infiltrated more than the photoresist film PR into which the material is infiltrated. The first gas is a hydrogen-containing gas (e.g., a H₂ gas), and the second gas is an oxygen-containing gas (e.g., an O₂ gas). Thus, the patterning method may perform the etching with higher selectivity of the exposed portion EP and the unexposed portion UP.

Although various exemplary embodiments have been described above, the present disclosure is not limited to the exemplary embodiments described above, and various omissions, substitutions, and changes may be made. In addition, elements in different embodiments may be combined to form other embodiments.

For example, while the above embodiment has described the case in which the substrate W is a silicon substrate as an example, the present disclosure is not limited to this embodiment. The substrate W may be, for example, a silicon substrate; a glass substrate; a transparent electrode such as ITO; a metal substrate such as gold, silver, copper, palladium, nickel, titanium, aluminum, tungsten or the like; a plastic substrate; and a substrate made of a composite material thereof.

The following supplementary notes are further provided for the above embodiment.

### Supplementary Note 1

A patterning method includes:
an infiltration operation of infiltrating, into a photoresist film, a material for increasing a selectivity of an exposed portion and an unexposed portion formed by exposure on the photoresist film provided on a surface of a substrate; and
an etching operation of dry-etching the photoresist film on which the infiltration operation has been performed.

### Supplementary Note 2

In the patterning method of Supplementary Note 1 above, the infiltration operation includes exposing the substrate to a gas containing the material.

### Supplementary Note 3

In the patterning method of Supplementary Note 1 or 2 above, the infiltration operation includes infiltrating, into the photoresist film, the material deeper into the unexposed portion than the exposed portion.

### Supplementary Note 4

In the patterning method of any one of Supplementary Notes 1 to 3 above, the material is a metallic element or a metalloid element.

### Supplementary Note 5

In the patterning method of Supplementary Note 4 above, the metallic element is any one of aluminum, titanium, and germanium.

### Supplementary Note 6

In the patterning method of Supplementary Note 4 above, the metalloid element is silicon.

### Supplementary Note 7

In the patterning method of any one of Supplementary Notes 4 to 6 above, an amount of infiltration of the metallic element or the metalloid element into the photoresist film is in a range of 4 atomic % to 20 atomic %.

### Supplementary Note 8

In the patterning method of any one of Supplementary Notes 1 to 7 above, the etching operation includes etching the exposed portion deeper than the unexposed portion.

### Supplementary Note 9

In the patterning method of any one of Supplementary Notes 1 to 7 above, the etching operation includes: performing a first etching with a first gas capable of etching the photoresist film into which the material is infiltrated, up to a depth, which is deeper than a depth to which the material is infiltrated into the exposed portion and shallower than a depth to which the material is infiltrated into the unexposed portion; and subsequently, performing a second etching with a second gas capable of etching the photoresist film into which the material is not infiltrated more than the photoresist film into which the material is infiltrated.

### Supplementary Note 10

In the patterning method of Supplementary Note 9 above, the first gas is a hydrogen-containing gas, and the second gas is an oxygen-containing gas.

### Supplementary Note 11

In the patterning method of Supplementary Note 9 or 10 above, the first gas is a H₂ gas, and the second gas is an O₂ gas.

### Supplementary Note 12

A patterning device includes:
an infiltration processor configured to infiltrate, into a photoresist film, a material for increasing a selectivity of an exposed portion and an unexposed portion formed by exposure on the photoresist film provided on a surface of a substrate; and
an etching processor configured to dry-etch the photoresist film on which the infiltration operation has been performed.

### EXPLANATION OF REFERENCE NUMERALS

1: patterning device, 11: infiltration processor, 12: etching processor, EP: exposed portion, PM: photomask, PR: photoresist film, UP: unexposed portion, W: substrate

What is claimed is:

1. A patterning method, comprising:
an infiltration operation of infiltrating, into a photoresist film, a material for increasing a selectivity of an exposed portion and an unexposed portion formed by exposure on the photoresist film provided on a surface of a substrate; and
an etching operation of dry-etching the photoresist film on which the infiltration operation has been performed.

2. The patterning method of claim 1, wherein the infiltration operation includes exposing the substrate to a gas containing the material.

3. The patterning method of claim 1, wherein the infiltration operation includes infiltrating, into the photoresist film, the material deeper into the unexposed portion than the exposed portion.

4. The patterning method of claim 1, wherein the material is a metallic element or a metalloid element.

5. The patterning method of claim 4, wherein the metallic element is any one of aluminum, titanium, and germanium.

6. The patterning method of claim 4, wherein the metalloid element is silicon.

7. The patterning method of claim 4, wherein an amount of infiltration of the metallic element or the metalloid element into the photoresist film is in a range of 4 atomic % to 20 atomic %.

8. The patterning method of claim 1, wherein the etching operation includes etching the exposed portion deeper than the unexposed portion.

9. The patterning method of claim 1, wherein the etching operation includes:
performing a first etching with a first gas capable of etching the photoresist film into which the material is infiltrated, up to a depth, which is deeper than a depth to which the material is infiltrated into the exposed portion and shallower than a depth to which the material is infiltrated into the unexposed portion; and
subsequently, performing a second etching with a second gas capable of etching the photoresist film into which the material is not infiltrated more than the photoresist film into which the material is infiltrated.

10. The patterning method of claim 9, wherein the first gas is a hydrogen-containing gas, and the second gas is an oxygen-containing gas.

11. The patterning method of claim 9, wherein the first gas is a H₂ gas, and the second gas is an O₂ gas.

12. A patterning device, comprising:
an infiltration processor configured to infiltrate, into a photoresist film, a material for increasing a selectivity of an exposed portion and an unexposed portion formed by exposure on the photoresist film provided on a surface of a substrate; and
an etching processor configured to dry-etch the photoresist film on which the infiltration operation has been performed.
